(19) United States
(12) Patent Application Publication
(10) Pub. No.: US 2015/0090953 A1
(43) Pub. Date: Apr. 2, 2015

(54) Materials with Tunable Properties and Memory Devices and Methods of Making Same Using Random Nanowire or Nanotube Networks

(71) Applicant: The Provost, Fellows, Foundation Scholars, and Other Members of Board, of the College of the Holy, Dublin (IE)

(72) Inventors: John Boland, Dublin (IE); Jonathon Coleman, Dublin (IE); Mauro Ferriera, Dublin (IE)

(21) Appl. No.: 14/398,642

(22) PCT Filed: May 3, 2013
(86) PCT No.: PCT/EP2013/059292

§ 371 Date: Nov. 3, 2014

(30) Foreign Application Priority Data
May 4, 2012 (EP) 12166844.6

(51) Int. Cl. H01L 45/00

(52) U.S. Cl. CPC H01L 45/122; H01L 45/146; H01L 45/1253
USPC 257/4; 252/62.3 E

(57) ABSTRACT

A device comprising a first electrode; a second electrode; and an active material positioned between the first and second electrode, wherein the active material comprises a plurality of randomly positioned conducting wires coated with a nanoscale switchable dielectric layer, said conducting wires are adapted to provide a conducting path or paths when a voltage is applied by one of the electrodes or between said electrodes.

### FIELD OF THE INVENTION

This invention describes a new type of material, that is easy to fabricate, whose properties are non-volatile and can be tailored across a wide range of values, and provides a novel multilevel memory capability.

### BACKGROUND TO THE INVENTION

Nanoscale materials are beginning to find applications in many areas of devices, sensors, displays and medical technologies. Early efforts to exploit the potential of individual wires have met with limited success due to variations in is properties among individual wires and challenges associated with the placement of these wires at prescribed locations. Consequently, there has been a growing interest in the use of nanowire networks (NWNs), where placement is no longer an issue and differences in properties are averaged out. These advantages, in combination with the superior mechanical properties of these material systems and the ability to spray deposit them over large areas, for example as disclosed by. De, S. et al. Silver Nanowire Networks as Flexible, Transparent, Conducting Films: Extremely High DC to Optical Conductivity Ratios. Acs Nano 3, 1767-1774, doi:10.1021/nn900348c (2009) and Scardaci, V., Coull, R., Lyons, P. E., Rickard, D. & Coleman, J. N. Spray Deposition of Highly Transparent, Low-Resistance Networks of Silver Nanowires over Large Areas. Small 7, 2621-2628, doi: 10.1002/smll. 201100647 (2011), make NWNs attractive for a wide range of applications.

The performance of any NWN is determined by the connectivity between individual wires within the network and in particular how information or charge is carried across the network from an array of electrodes that contact and interrogate it. Intuitively, one might expect the behaviour to depend on the wire physical dimensions, the properties of the inter-wire junctions, the density and thickness of the network and the relative size and spacing between electrodes. Earlier literature studies have addressed the on-set to conduction and the formation of percolation channel across ultra-sparse wire networks or composites.

A paper by White et al entitled ‘Resistive Switching in Bulk Silver Nonaire Polystyrene Composites’ ADVANCED FUNCTIONAL MATERIAL, Wiley-V C H Verlag GMBH & Co. KGAA, DE, VOl. 21, no. 2 21 Jan. 2011, pages 233-240 discloses resistive switching in Ag nanowire-polymer composites. Switching is observed only for specific compositions close to the percolation threshold and is only observed for Ag wires. Switching was ascribed to the formation of Ag filament between wires, that can is some cases be reversibly made, broken and re-formed. The on/off ratio and extent of reversibility generally decayed after a few cycles. The authors demonstrated that switching is not observed in polymer composites containing Cu wires or CNTs—the former due to the thickness of the polymer makes for too large a barrier for filament formation while for CNTs the strong covalent bonding present prevents any kind of filament formation.

Another paper by Pradhan et al entitled ‘Electrical Bistability and memory phenomenon in carbon nanotube conjugated polymer matrixes’ JOURNAL OF

PHYSICAL CHEMISTRY. B MATERIALS, SURFACES, INTERFACES AND BIOPHYSICAL, WASHINGTON D.C., vol. 110, 27 Apr. 2006, pages 8274-8277, describes resistive switching in composites comprised of functionalized MWCNTs in conducting polymers. A large volume fraction of MWCNTs is used e.g. 3.3-33.0 wt %—with an increasing off-current at higher loading. Switching was ascribed to charge transfer from the tube into the conducting polymer. However the polymer required must be conducting.

However a problem with the NWN's to date, and above mentioned paper publications, is that engineers and materials scientists have struggled to utilise the nano-wires in a controllable way to make reliable electronic devices or circuits. At issue is that the vast majority of NWs available contain a natural passivation layer that is a barrier to conduction and device operation. The only exceptions are expensive noble metals such as Au and Ag, and CNTs, but in practice even in these cases great care is needed to removed surfactants or other unwanted coating that are present on these wires. Moreover, difference in the properties of individual wires, result in significant difference in the operating voltages between devices making the integrated circuit unworkable. In the most extreme case, as in the case of carbon nanotubes, a significant fraction of the tubes are metallic and hence unusable for memory or logic device application. However there are at present no effective methods to separate the useful semiconducting tubes from the metal ones.

It is an object of the invention to provide electronic materials and devices using nanowire networks.

### SUMMARY OF THE INVENTION

is According to the invention there is provided, as set out in the appended claims,

a device comprising:
a first electrode;
a second electrode;
an active material positioned between the first and second electrode, wherein the active material comprises a plurality of randomly positioned conducting wires coated with a nanoscale surface passivation layer, said conducting wires are adapted to provide a conducting path or paths when a voltage is applied by one of the electrodes or between said electrodes; and
wherein the conductivity of the paths can be controlled by application of the applied voltage.

The active material or layer in the device comprises a sparse random network of metallic or semiconducting nanowires (including phase change materials) or carbon tubes (single or multi-walled) that are coated with a spacer layer of controlled composition or covered by a natural oxidation or passivation layer. The network is deposited (sprayed, solution cast etc) as a large area film of controlled thickness (from a few 10's of nm to microns) on an insulating substrate. The spacer layer may be a polymer, any kind of passivation layer (oxide—native or otherwise, sulphide etc), the outer layer of a coaxial nanowire structure (e.g. TiO2 coated Ag nanowire) or some form of chemical functionalization. The uniformity and thickness of the spacer layer need not be precisely controlled but sufficiently thin to allow conduction by a switching mechanism. The spacer layer must be switchable under the action of external stimuli (electric field, radio-frequency and possibly light) so that it is possible to turn on and off the junctions formed between the wires. In some instance an irreversible spacer layer is useful, i.e. it goes from ON to OFF, but not to ON again or possibly OFF to ON but not ON to OFF again.

In a preferred embodiment the nanowires comprises a passivating oxide. For example the nanowires can be Ni, Cu etc or indeed any wire system that is suitably coated. The wires are in physical contact within the network and no polymer is employed. Switching is possible at all wire densities (unlike the prior art, such as White et al.) since wires that make numerous contacts with other wires facilitates filament formation that proceeds easily through the nanoscale oxide passivation layers. Importantly this enables the use of Cu, Ni and other inexpensive metal wires.

In one embodiment the use of nanoscale insulating coatings that can be controllably broken-down by the application of an electric (or some other) field.

The active areas of nanowire network are then defined by contacting the network with pairs of electrodes so as to apply a voltage bias across the areas of the film in between. These electrodes can be positioned in same plane creating a lateral device, or in a cross-bar configuration in which the network in sandwiched between crossed bar-shaped electrodes, either singly or as arrays.

An important aspect of the device geometry of the present invention is that the wires are randomly positioned and although the spacer layer has a well-defined composition there are random uncontrollable variations in spacer layer uniformity along the wire, so the junctions between wires have a distribution of properties (such as breakdown characteristic, tunnel barriers). Therefore there will be a distribution of ON and OFF voltages whose values will depend on the local properties of the spacer layer. Consequently the junctions do not all turn ON or OFF at once, rather the transition between ON and OFF states can be continuously controlled.

In one embodiment the active material comprises sparse random network of metallic or semiconducting nanowires or tubes and coated with a spacer layer of controlled composition.

In one embodiment the spacer layer comprises at least one of a passivation layer, electroactive material or some form of chemical functionalization.

In one embodiment application of a bias voltage across the active material creates a randomly varying voltage distribution.

In one embodiment application of a bias voltage across the active material creates a randomly varying voltage distribution that evolves in time, the rate of evolution being controlled by the applied voltage.

In one embodiment the first electrode and second electrode are positioned at a distance apart such that the device is configured to operate as a unipolar resistive switch. Suitably the distance is approximately 10-20 μm, though the integration density and electrode spacing is determined by the physical size (diameter and length) of the wires used.

In one embodiment the electrodes are arranged in a cross-bar geometry and the electrodes are separated by the thickness of the network layer.

In one embodiment the first electrode and second electrode are positioned laterally at a distance apart such that the device is configured to operate as a memristor device with continuously tunable conductivity. Suitably the distance is approximately 600 μm.

In one embodiment the combination of wires and junctions described herein can be modelled as a leaky resistor-capacitor network. Application of a bias voltage across the network creates a randomly varying voltage distribution. Network junctions store charge but weak junctions within the network respond by leaking charge (electrons/ions) to create connectivity cells involving a small number of neighbouring junctions that are bounded by higher barrier junctions that remain stable or OFF at this bias. Application of larger voltages causes these cells to grow and ultimately join up to create conducting paths, whose extent can be confined by the dimensions of the biasing electrodes. Due to random variations in junction properties the network will self-select one or a few paths out of the many possible paths across it. Increasing both size and separation between electrodes or the network density increases the number of possible parallel paths leading to enhanced levels of connectivity. As the voltage increases, additional paths are activated and the connectivity continues to evolve, ultimately leading to a memristive-like material behaviour, as described in more detail below with respect to the figures.

In one embodiment the resistance of the network materials can be continuously controlled from a very large value corresponding to the initially deposited network with all the junctions turned OFF to a value where all the junctions are turned ON, and to any value in between. The ability to operate with any desired resistance in this range is due to the fact that switching is an activated phenomenon and that material can be operated at low voltages where switching cannot occur.

In another embodiment the network is programmed spatially to exhibit different switching behaviours locally. This can be realised by patterning electrodes at small separations (optimally 10-20 um) to create resistive switching regions, where other regions of the same network are patterned at larger separation (optimially 200-600 um) and behave as memristive materials with controllable conductivity.

In another embodiment, arrays of electrodes (normal metal or transparent conductor e.g. ITO) can be positioned across the network to effect activation of the network regions in between so as to generate a macroscopic network material of arbitrary dimension.

In another embodiment the network material comprises nanowires that have a native oxide can be used to fabricate a memory device by placing the electrodes at small separations (about 2× average NW length) The I-V characteristic show a hysteretic loop and the system can be repeatedly switched between ON and OFF states. This type of resistive switching is well known in metal-oxide-metal film devices and is the basis for resistive random access memory (RRAM) technologies. Although in this particular implementation the device exploits the same physical phenomenon, the advantage of the present approach is that fabrication is inexpensive (spray deposition followed by contacts) and the network also provides for the potential to controllably influence the interactions between neighbouring cells leading to multi-level memory both locally and proximally.

In another embodiment the network is comprised of phase change NWs and voltage pulses applied to the network causes localised phase changes to occur at the resistive junction locations, and whose extent can be controlled by increasing the pulse duration.

In another embodiment the nanowires are coated with TiO2 and annealed before network formation to generate oxygen vacancies at the surface of the oxide coated nanowires. After network deposition the network is then electrically poled to cause the charged oxygen vacancies to diffuse preferentially to one side of the junctions that comprise the network thereby creating a reversible memristor network in which the resistance can be reversibly and arbitrarily controlled over a large range.

In another embodiment the performance of the network is controlled by introducing small quantities of noble nanowires (e.g. Au or Ag) that do not have surface coatings and which effectively dope the network by enhancing local connectivity and modify the materials turn on characteristics.

In a further embodiment active material suitable for use between a first and second electrode, wherein the active material comprises a plurality of randomly positioned conducting wires and a passivation oxide layer, said conducting wires are adapted to provide a conducting path or paths when an electric field is applied by one of the electrodes or between said electrodes.

In one embodiment the conductivity of the paths can be arbitrarily controlled by application of the electric field.

In one embodiment a random nanowire network wherein connectivity and conductivity between nanowires can be arbitrarily controlled by the application of an electric field.

In one embodiment the conductivity can be programmed to a set value.

In one embodiment conductivity and switching properties are length scale dependent.

In one embodiment the length scale dependent properties can be realised by interrogating with contact electrodes. An additional advantage of the present invention is the low cost of fabrication. Instead of using costly lithography and processing tools to create patterned materials, fabrication involves simple spray deposition, or other such low cost deposition techniques, of a sparse nanowire network. The level of integration can be increased by controlling the length of the nanowires.

### BRIEF DESCRIPTION OF THE DRAWINGS

The invention will be more clearly understood from the following description of an embodiment thereof, given by way of example only, with reference to the accompanying drawings, in which:

FIGS. 1a to 1f illustrates a number of images of the active material according to the invention;

FIG. 2 illustrates a number of graphs for different densities of nano-wires in the active material;

FIG. 3 illustrates I-V curves obtained for the active material switching for different voltage values where the electrodes are separated by small (A) and large (C) distances; Figure (B) shows passive voltage SEM imaging of the active material;

FIG. 4 illustrates, similar to FIG. 3A and 3C, I versus V characteristics of an Ag NW network coated with a nanoscale polymer surfactant coating but for the case when the separation between the electrodes is large. The inset shows the continuous range of controlled conductivities possible;

FIGS. 5a and 5b illustrate the behaviour of Ni NW networks at different length scales where the distance between a first and second electrode is varied, according to one embodiment of the invention;

FIGS. 6a and 6b illustrate images in detail the establishment of a contact at small electrode separations showing a device according to the invention;

FIGS. 7a, 7b, and 7c illustrates three images showing the evolving connectivity seen by SEM as a function of applied bias applied across a

Ni nanowire network;

FIGS. 8a and 8b illustrates images of a sparse (T=85%) Ag nanowire network with large electrode separation that has undergone activation;

FIG. 9 (A) Resistive switching a sparse (T=90%) Ni NW network device fabricated by shadow-mask deposition of Ni electrodes (I, II, & Ill). Scale bar is 100 μm. Inset shows close-up image of 10 μm gap (I-II). Scale bar is 5 μm. (B) Highly repeatable switching of device addressed via electrodes I-II. (C) Activation of metallic connection formed between electrodes II-III. Inset shows stable metallic interconnect. (D) Operation of the I-II device via the II-III interconnect, all within the same network; and

FIG. 10 illustrates results for repeated switching of the device in FIG. 9. The on-off ratio is greater than 10,000 and the on and off levels exhibit good stability.

### DETAILED DESCRIPTION OF THE DRAWINGS

The invention is a device comprising an active material positioned between a first and second electrode, wherein the active material comprises a plurality of randomly positioned conducting wires. The conducting wires are adapted to provide a conducting path when a voltage is applied by one of the electrodes or across the electrodes. The active material of the invention is a material that forms a filament or whose resistance can be controlled by applying a voltage and has a plurality of conducting wires to provide a nano-wire network (NWN).

The invention utilises intrinsic connectivity within well-formed NWNs comprised of wires with dielectric, resistive-switch, conducting oxide or other surface coatings or functionalisations.

The network behaviour of the active material falls into two broad regimes or embodiments, characterised by how the voltage threshold scales with the network density for different distance separations between the electrodes, described in more detail below.

For sparse networks at small separations the activated network behaves like a device with well-defined hysteresis-free I-V curves due to the activation of one or a small number of conducting paths. The number of paths depends on the strength of the junctions and the magnitude of the applied field. For dense networks at large separations, the I-V curves for the activated network show clear evidence of accumulating hysteresis and memristance. The latter is due to the vast number of parallel paths between the electrodes, and a bias-dependent connectivity that allows the system to evolve and exist along a continuum of well-defined conductance states. This multiplicity of parallel paths also provides an effective redundancy within the network that enables healing and self-repair. This demonstrates that these behaviours are intrinsic properties of random NWN, independent of the wire or the surface coating, and provides potential device and materials applications.

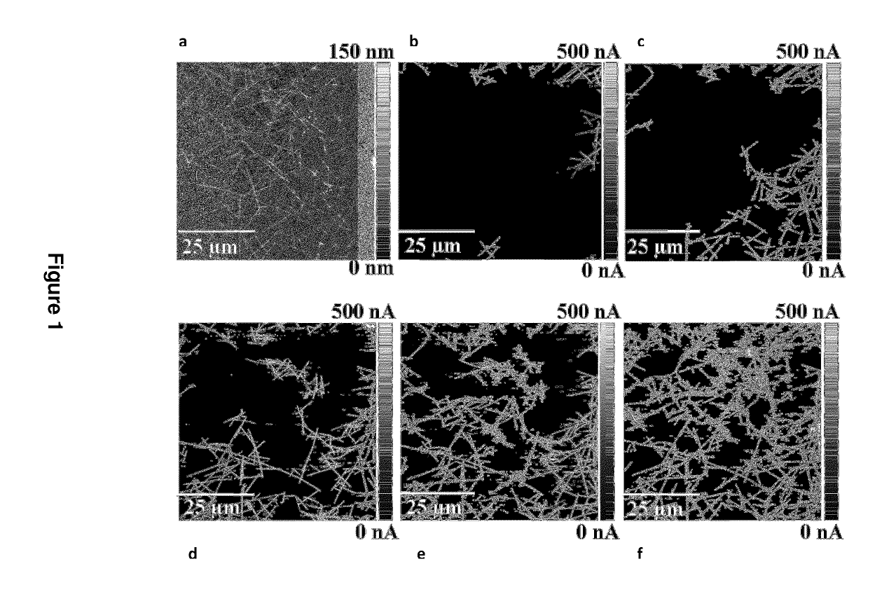

The active material of the present invention comprises network films and can be formed by spray deposition of poly-vinylpyrollidone (PVP) surface-coated Ag NWs and surface oxide passivated Ni NWs onto SiO₂ substrates. Metal contact electrodes are subsequently deposited to enable transport measurements between pairs of electrodes at fixed separations or between a single electrode and a conducting atomic force microscopy (CAFM) probe. The latter method has the advantage that the metal-coated AFM probe acts as a mobile nanoscale contact that can generate simultaneous topographic and conductance maps. Previous studies have shown this method to be capable of analysing the junction resistance between SWCNTs and graphene flake networks and the contact resistance between individual SWCNTs and metal electrodes. The metal coated tips used (Pt/Cr, 0.2 N/m, Cont E, Budget Sensors) were maintained at a constant loading force of 1 nN during normal imaging whereas the loading force was increased to ˜2.5 nN when performing local tip induced electrical activation experiments as described below in more detail with respect to FIG. 1.

Referring to FIGS. 1a to 1f illustrates a number of images of the active material according to the invention. FIG. 1a shows local electrical activation of Ag NWN via a Pt/Cr coated AFM tip and the topography of a random network of Ag nanowires. A metal coated AFM tip was used to locally activate sites in the network by applying a threshold voltage of 6 V for ˜2 seconds and then imaging the same network region under a lower bias of 200 mV. The current maps shown in images b, d, e and f are a result of applying the voltage pulses at selected regions marked 1, 2, 3, 4 and 5 on the topographic map. The network can be seen to turn on locally as the wires become connected due to the local probe excitation. Note the contact electrode is located at the top of the image.

The inventors discovered that the Ag NW network failed to conduct under low bias voltage conditions (200 mV) even though the wires were physically connected to each other and to the contact electrode (FIG. 1a). Clearly the presence of the PVP surfactant layer impedes conduction. This is consistent with the fact that heat treatment to eliminate the surfactant ultimately produces networks that have conductivities as high as 5×10⁶ S/m.⁸ Increasing the tip-electrode bias in small steps from 10 mV reveals that there exists a well-defined threshold voltage to activate conduction between the probe and the electrode and by locally applying voltage pulses above this threshold it is possible to investigate the connectivity within the NWN. FIG. 1 b shows the result following application of a 6 V-2 sec pulse at location 1 in FIG. 1a after which the tip was withdrawn and the entire surface was re-imaged at 200 mV. Clearly this local region of the network is now conducting. Note the Pd contact electrode is not shown but located at the top of the image. Repeating this process at locations 2 through 5, resulted in the current maps shown in FIG. 1c-f, and following which the majority (but not all) of the network became conducting. These data clearly show that electrical conduction is activated and results in irreversible breakdown of the surfactant material present at the nanowire junctions.

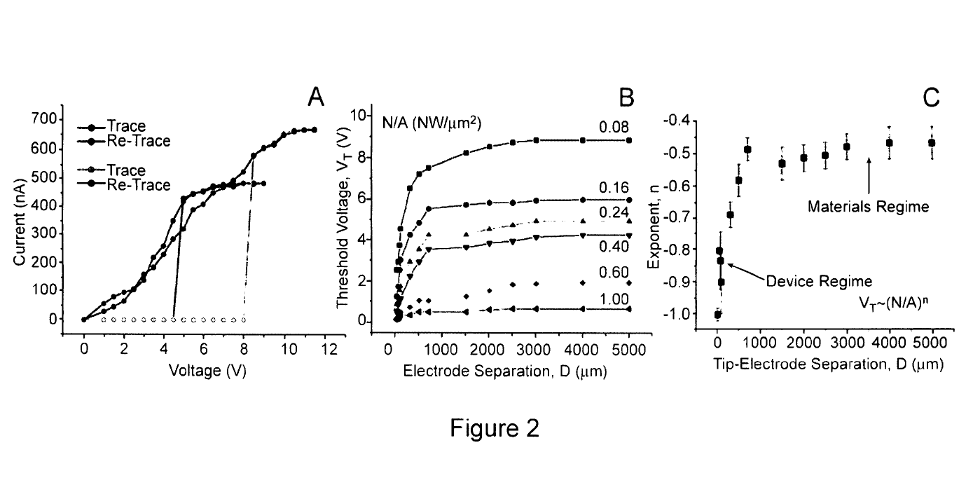

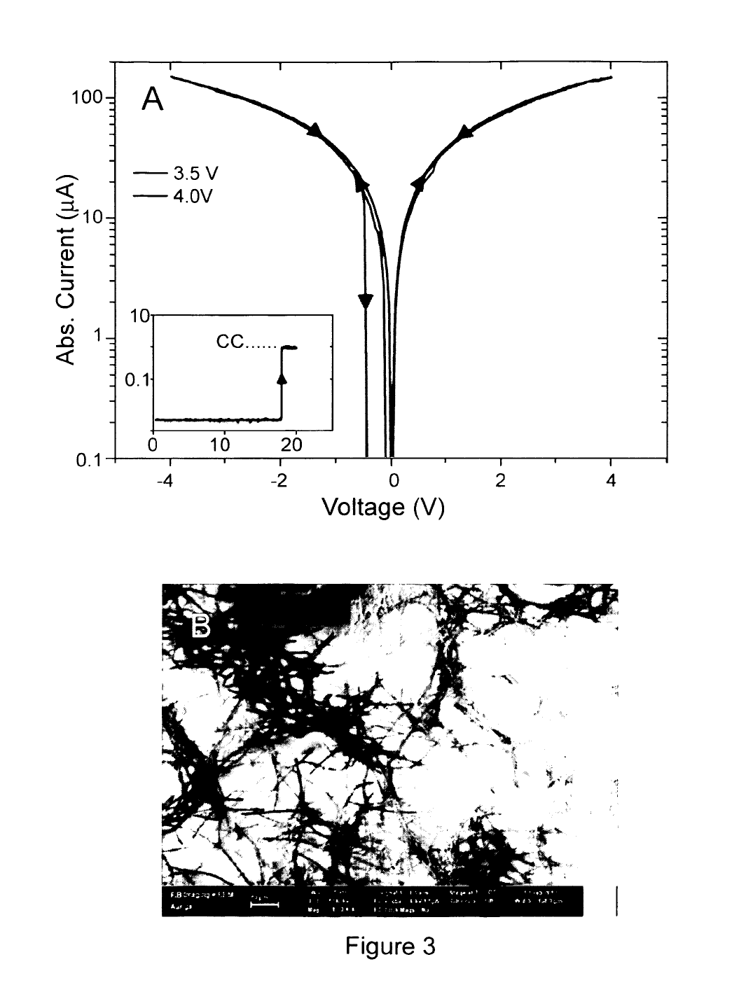

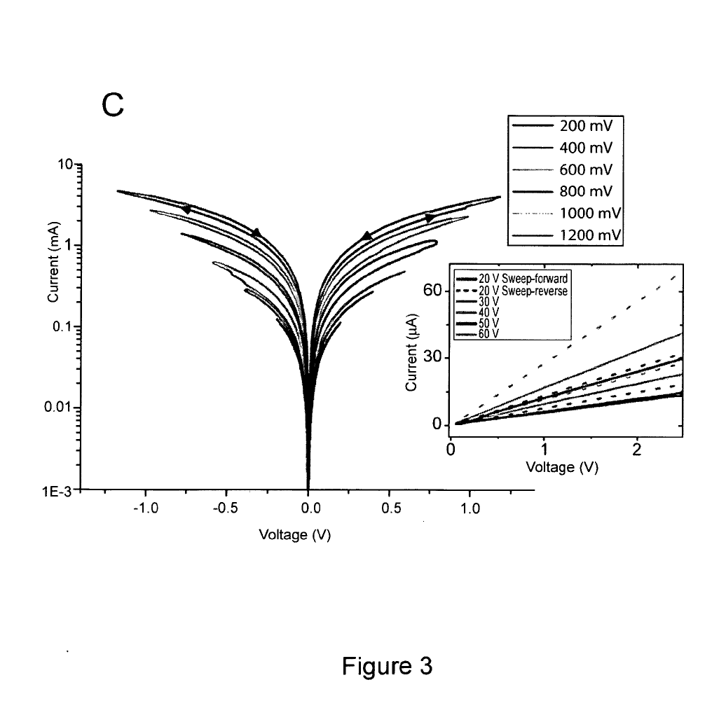

Importantly, it is observed that the threshold voltage, V_{T}, required to activate the network is different for different networks, and for a given nanowire type it depends in particular on the distance from the electrode and the thickness or density of the NWN, as illustrated in FIGS. 2 and 3. It will be appreciated that for nanowires that form networks with more resistive junctions, the operation threshold and operating conditions require higher voltages.

FIG. 2a shows typical I-V curves measured for the case of a sparse NWN (optical transmission T=85%) with tip-electrode separations of 100 and 700 μm. Each I-V shows an abrupt well-defined threshold or forming voltage that increases with the distance from the electrode. In each case the retrace show that the network has been locally turned on, which was confirmed by current mapping (not shown). The observed increase in threshold voltage with distance is consistent with an increased number of junctions that have to be broken down between the electrodes.

FIG. 2b shows the threshold voltage V_{T} as a function of tip-electrode separation for NWNs of different network densities (i.e. thicknesses) using large electrodes that were fabricated by a combination of lithography and deposition through a shadow mask. Note that the thickness was measured optically (% transmission T) and transformed into the number of nanowires per unit area, N/A. The threshold voltage is observed to plateau beyond a certain distance from the electrode. The overall shape of the curve is similar regardless of the NWN density, except that the plateau value steadily decreases as the network density increases, consistent with an increase in the number of parallel paths between the two electrodes (see below). Consequently, in the case of denser NWNs the application of a single, relatively low voltage pulse at any one location has the effect of turning on the network region between the electrodes.

Whereas FIG. 2b shows threshold voltage V_{T} as a function of electrode separation D, for various film densities N/A, this data can easily be re-plotted to show V_{T} as a function of N/A for various values of D on a log-log scale. The resulting data are well described by a power law of the form V_{T}–(N/A)ⁿ, and the measured exponents n are plotted as a function of D in FIG. 2c. It is noted that the exponent n increases sharply from −1 at small D to −½ for larger tip-electrode separations. It can be demonstrated that this scaling behavior is an intrinsic property of NWNs and leads to the creation of novel materials and devices properties and the ability to programme the network to produce either or both types of behaviour.

To illustrate and better understand the different threshold behaviours at small (n=−1) and large (n=−½) electrode separations were tested and the I-V characteristics were examined following activation of the Ag NWN. In all cases electrodes were defined using lithography and/or shadow masks and for convenience the electrode width W was set equal to the electrode separation D. Initially the network was activated by setting the current compliance to some nominal level (typically 1000 nA) to determine the threshold voltage for conduction across the network. Once activated, I-V curves were measured by sweeping the voltage over the range: 0→Nₘₐₓ→0→−Vₘₐₓ→0, which was repeated on each I-V cycle. In the case of large electrode separations the magnitude of Vₘₐₓ was gradually increased to help visualise the evolution in the network connectivity. FIG. 3A shows the case of a low density network (optical transmission T=85%) with D=W=40 μm for which the n=−1 behaviour is expected to be the most pronounced (see FIG. 2c). Once the forming voltage had been reached (˜0.4V), I-V curves recorded at both polarities are reproducible and show no evidence of hysteresis. The 40 μm separation is several times the average NW length (7 μm for Ag NWs) and necessitates the activation of a number of junctions along the conducting path. Reversible I-Vs are consistent with the formation of a single or small number of well-defined and stable conducting paths between the electrodes.

The origin of this conduction behaviour can be directly visualised using passive voltage contrast SEM imaging, where the electrode or electrodes are electrically grounded to provide contrast between connected and unconnected wires in the NWN (FIG. 3B). Wires in the network that are connected to each other and to the electrodes appeared darker due to reduced charging. Clearly just a single or small number of paths are activated in this n=−1 regime.

The behaviour is different in the n=−½ regime. FIG. 3C shows the I-V data for a higher density Ag network (T=75%) at a large electrode separation (D=W=1000 μm). I vs V measurements in FIG. 3C exhibit a hysteresis phenomenon that evolves and grows with each I-V cycle. It is important to note that the hysteretic behaviour occurs only at larger voltages, such that the electrical properties of the network are stable under low bias conditions. This is clearly shown in the inset in FIG. 3C (note current displayed in μA's) which demonstrates that the conductivity of the activated network can be controllably and continuously manipulated over a very broad range. The lower bound is determined by the set compliance current used in the network activation process, while in principle the upper bound is controlled by the properties of the fully connected NW network.

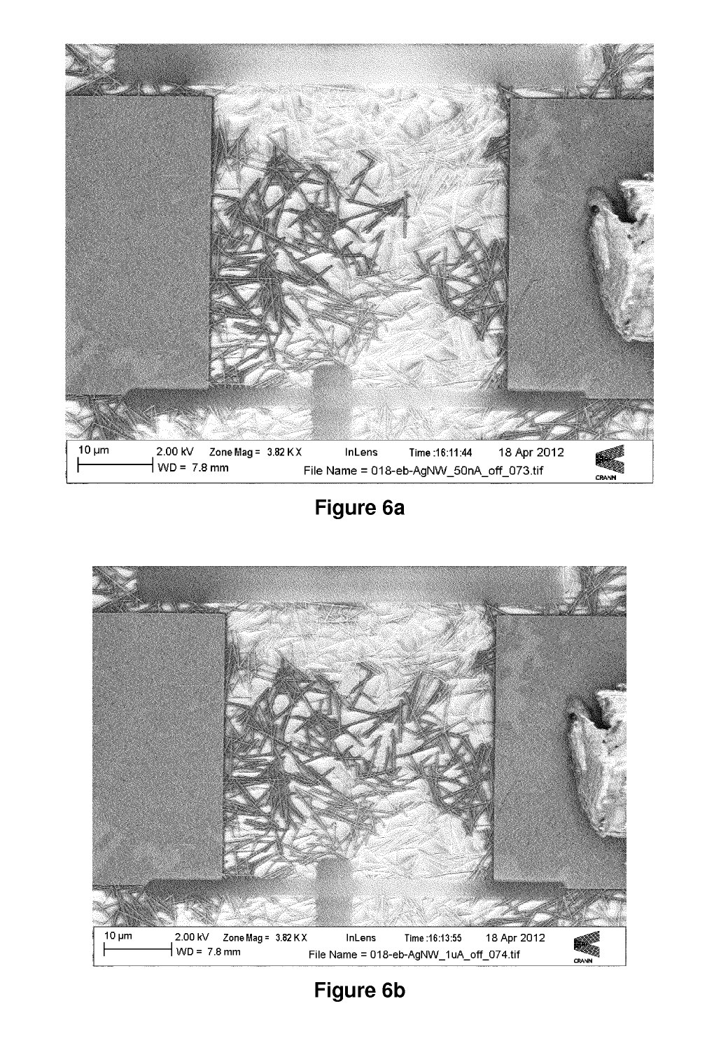

The hysteresis observed in FIG. 3C is a consequence of the large number of parallel conduction pathways between the well separated electrodes deposited on denser networks together with a bias-dependent activation of these pathways that causes the network connectivity to evolve and grow during each I-V cycle. The result is a network whose connectivity and hence conductivity can be tuned over a wide range as described in FIG. 3C. This evolving connectivity is directly visualised in FIGS. 6a and 6b by comparing SEM images of the network at different stages in the I-V cycle. The connected (darker) wires in the top panel are seen to grow in number and density in the bottom panel. The uniformity of this evolving connectivity is clearly dependent on the quality of the original network and the deposition and network activation process need to be optimised to insure uniform connectively over large areas.

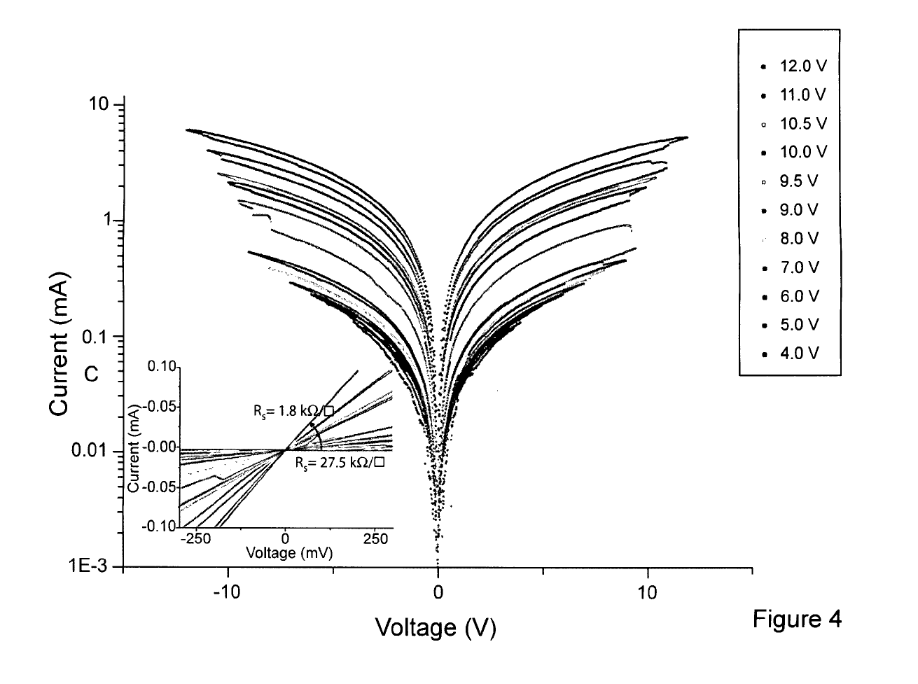

FIG. 4, similar to FIG. 3, illustrates Log I vs V characteristics of an Ag NW network in which the wires are coated with a nanoscale polymer surfactant, for example PVP. The separation between electrodes is 1000 μm. Clear hysteresis loops are seen due to evolving connectivity in the network at increasingly higher biases and the inset shows the range of tuneable conductivities available

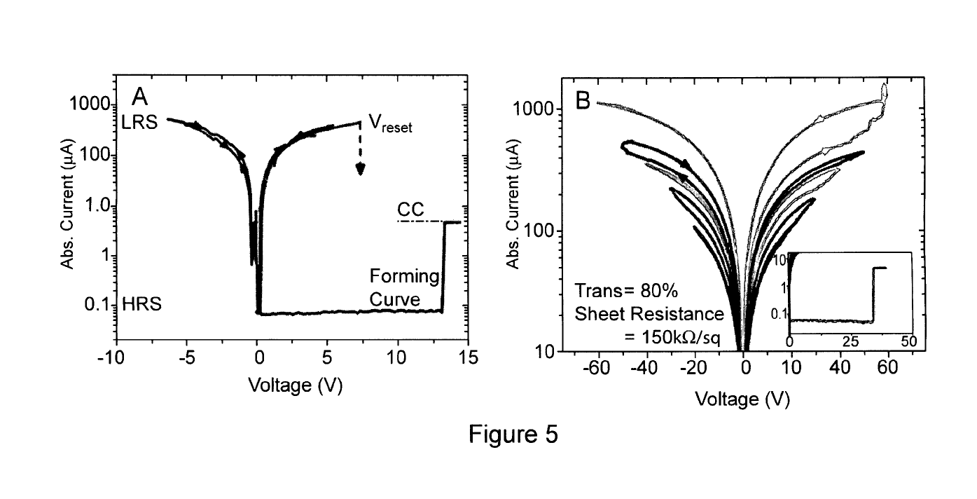

To demonstrate that this behaviour is a not unique to PVP-coated Ag NW networks, Ni NWs with NiO network junctions were also studied. Ni/NiO/Ni planar junctions have been extensively studied and are known to undergo resistive switching (RS). These oxide barrier layers are more robust than PVP and thus expected to exhibit different activations characteristic. FIGS. 5a and b show the log I versus V data recorded in the n=−1 (D=W=20 μm) and the n=−½ (D=W=600 μm) regimes, respectively. Although the threshold voltage and current-voltage behaviours are different from PVP-coated Ag NWs, most notably the requirement for larger activation and drive voltages, there are also striking similarities.

FIGS. 5a and 5b illustrate the behaviour of Ni NW networks at different length scales. FIG. 5a illustrates a unipolar resistive switching comprising sparse nano-wire network having a thickness and/or distance between the electrodes of 20 μm. I-V behaviour traces the same path between 0 V and Vreset. However if the voltage is increased above Vreset the network immediately switches form the conducting low resistive state (LRS) to the high resistive state (HRS).

Surprisingly, despite the fact that switching involves the formation and rupture of metallic Ni filaments at network junctions these devices can be set and reset repeatedly under ambient conditions, presumably due to passivation by the surrounding oxide.

FIG. 5b shows that the behaviour of Ni networks at larger electrode separation (in this example a distance of 600 μm) is remarkably similar to that of Ag networks. I versus V measurements surprisingly reveal extraordinary levels of hysteresis over the entire voltage sweep. As in the case of Ag networks, hysteresis is a dynamic phenomenon and exhibits a strong voltage and time dependence. Connectivity, whether it involves dielectric breakdown of PVP or the growth of Ni filaments, is an activated process and will naturally select those junctions with the lowest barriers, i.e. lowest PVP or oxide thicknesses. In the case of Ni NW networks, the width and stability of the hysteresis loops is improved over that of Ag networks due to the greater stability of NiO over PVP, but necessitates larger operating voltages.

It will be appreciated that the combination of wires and junctions described herein can be modelled as leaky resistor-capacitor networks. Application of a bias voltage across the network creates a randomly varying voltage distribution. Network junctions store charge but weak junctions within the network respond by leaking charge (electrons/ions) to create connectivity cells involving a small number of neighbouring junctions that are bounded by higher barrier junctions that remain stable at this bias. Application of larger voltages causes these cells to grow and ultimately join up to create conducting paths, whose extent can be confined by the dimensions of the biasing electrodes to define the distance between thereof. Due to random variations in junction properties, at small inter-electrode separations the network will self-select one path or a few out of the many possible paths across it. Increasing both size and separation between electrodes increases the number of possible parallel paths leading to enhanced levels of connectivity. As the voltage increases, additional paths are activated and the connectivity continues to evolve, ultimately leading to the memristive-like behaviours in FIGS. 3c, 4 and 5b.

The nanowire networks described herein take advantage of the random properties of NWs and in particular natural variations that occur in the thickness and properties of surface coatings. As a result these systems display a deterministic response for small electrodes and small separations resulting in formation of well-defined conduction pathways, which ultimately evolves into a stochastic response at larger length scales where connectivity is controlled by the numbers of parallel paths and the distribution of junction properties. In contrast, NWs with perfectly controlled surface coatings would be of little interest since the entire network would become activated at once. This distribution of junction properties provides a handle to manipulate the connectivity and ultimately the properties of these network materials and devices. The present invention provides a materials technology platform that is capable of tuning the properties of NW networks and effectively exploiting the vast range of NW systems that have been developed over the past decade.

FIG. 6a and FIG. 6b illustrate in detail the establishment of a contact at small electrode separations showing a device according to the invention. The active material is positioned between the first and second electrode. As clearly shown the active material comprises a plurality of randomly positioned conducting wires. The conducting wires are adapted to provide a conducting path or paths when a voltage is applied by one of the electrodes or across the electrodes. FIG. 6a shows the network before electrical contact is made between the electrodes while FIG. 6b shows the device after electrical contact is made.

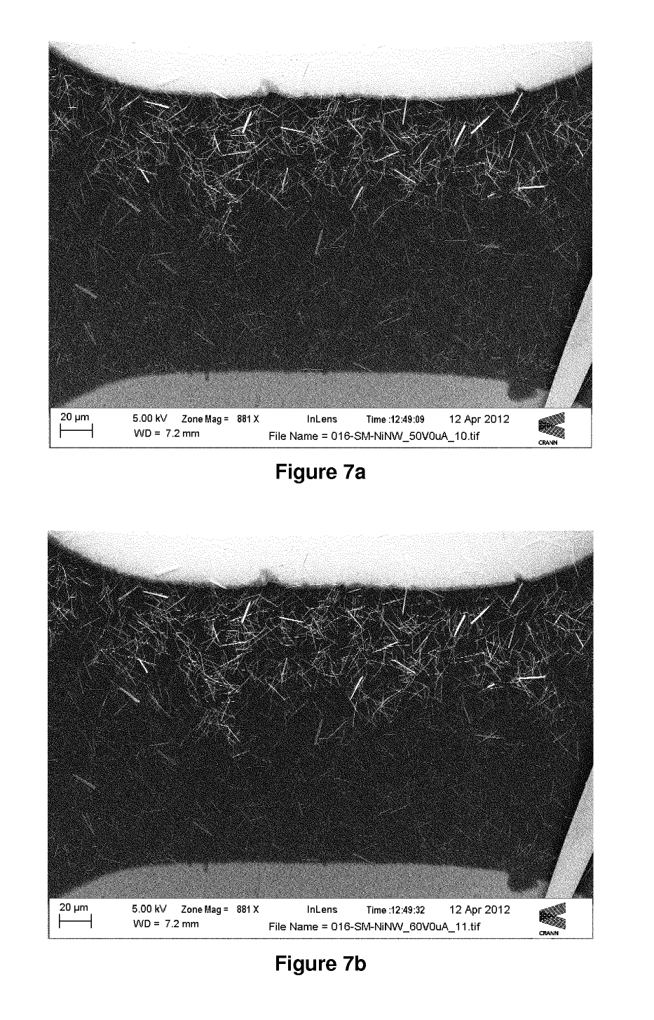

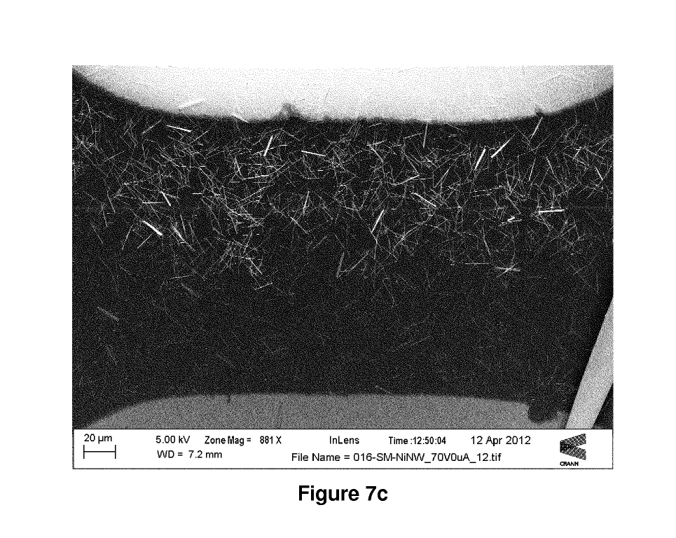

FIGS. 7a, 7b, and 7c illustrates three images showing the evolving connectivity seen by SEM as a function of applied bias applied across a Ni nanowire network, illustrated for an applied voltage of 50V, 60V and 70V respectively. When the NWs are connected together they are at the same potential as the contacting electrode and have similar brightness. Note that the evolving connectivity front that grows towards the other electrode. There is a similar front on the lower electrode that is not seen under these conditions. Note no current has as yet been passed thru the network, this is just the wires connecting up.

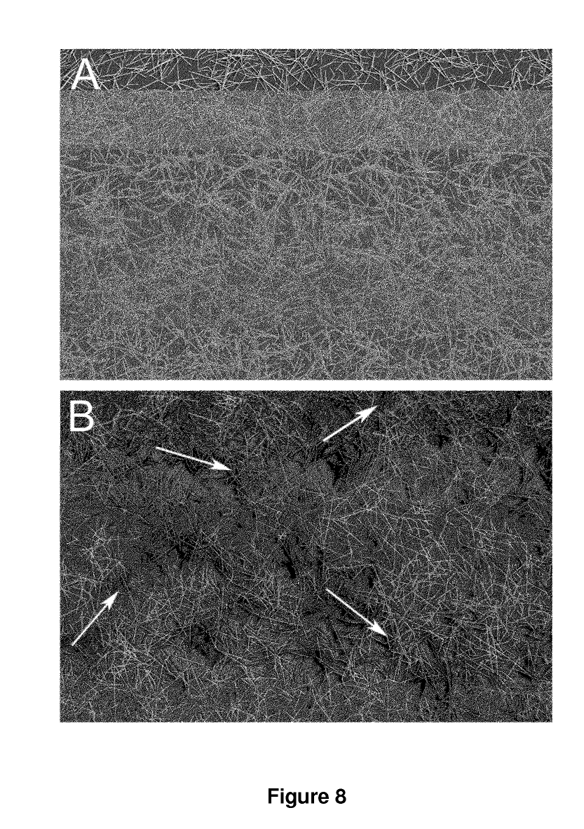

FIGS. 8a and 8b illustrates images of a sparse (T=85%) Ag nanowire network with large electrode separation that has undergone activation. FIG. 8A shows a uniform random network of nanowires but the standard SEM image reveals no evidence of activation. FIG. 8B illustrates a passive voltage contrast image (in lens detector) of the same region of the network that shows dark contrast regions due to the presence of conductive pathways, as illustrated by the arrows shown. It will be appreciated that the active layer can be made up of two or more layers of nano-wires to define a 3D structure of the active layer and arranged at a desired thickness.

It will be appreciated that an important aspect of the network materials of the present invention is their programmability. In the case of Ag wires coated with a nanoscale polymer dielectric successive electrical stressing events at increasingly higher electric fields leads to increased connectivity and conductivity. At any point, the material can be operated at low fields without further increasing the connectivity, so that the network represents a material with programmable conductivity (see FIG. 4). It will be appreciated that the nanowires implemented in the present invention will have passivations, functionalizations or coatings that have a thickness of 10 nm or less so as to enable connections between wires driven by electrical or other stimuli. The thickness of the coating is important. The length of the nanowire determines the inter electrode separation.

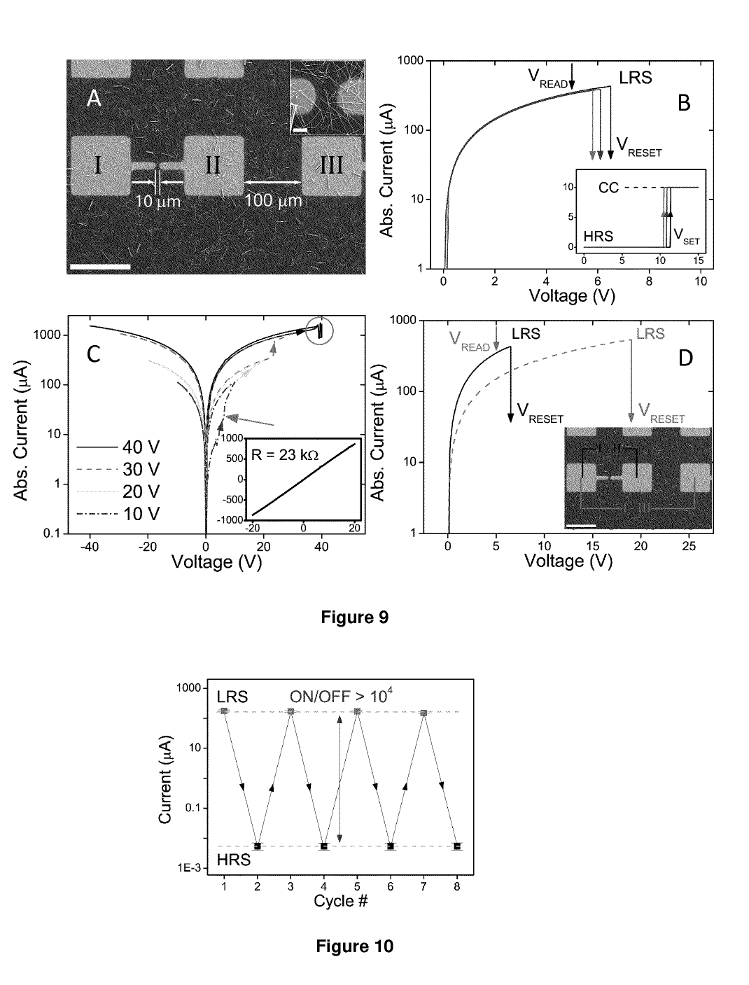

As the metallic wires have passivating oxides (e.g. Ni or Cu) there is no need for a polymer coating. In this case, rather than dielectric breakdown (as occurs in the polymer case) filaments are formed at the junction between wires, and the making and breaking of these filaments are responsible for resistive switching, causing the network to switch on and off. An important and enabling aspect of these networks is its different behavior at large and small electrode separations (see FIG. 2). This is demonstrated in FIG. 9 where a Ni network has been patterned to create gaps at 10 μm and 100 μm (FIG. 9A). FIG. 9B shows the behavior of the 10 μm gap (I-II) which exhibits reversible resistive switching between the HRS and the LRS. FIG. 9C shows the behavior of the 100 μm gap (II-III), which evolves connectivity and conductivity to establish a metallic interconnect with a resistance of 23 kΩ. Note resistive switching still can and does occur (see red circle in FIG. 9C) but the redundancy found in larger networks insures that the overall network remains on and conducting. FIG. 9D shows that it is possible to drive the device I-II using the network interconnect II-III. Note that for the red curve (which shows the device addressed through the network via contacts II-III) switching occurs at a higher voltage compared to black curve (where the device is addressed through the I-II contacts). This difference in voltage is due to a drop of part of the applied voltage across the 23 kΩ network. Thus the same network can be programmed to behave either as a switching device or a metallic interconnect.

FIG. 10 shows the on-off ratio of the device in FIG. 9 during repeated switching. The on-off ratio is much larger than that found in conventional planar resistive switching devices (>10⁴ vs. 100-200). The reason for this is the very small contact area between wires (not much larger than the nanoscale conducting filament itself) which minimizes the leakage current in the off state. Conventional planar devices have footprints well in excess 1000 nm² and have large leakage currents. Moreover, the fidelity of the on and off states is much sharper than in planar device since the same filament is made and broken in network devices, whereas the location and properties of the filament can change during the operation of a planar device.

Note that in addition to the planar device configuration shown in FIG. 9, it is possible to fabricate crossbar devices in which the network is sandwiched between addressable electrode lines. In this manner a half-select strategy can be employed to address and switch specific regions of the network.

In the specification the terms “comprise, comprises, comprised and comprising” or any variation thereof and the terms “include, includes, included and including” or any variation thereof are considered to be totally interchangeable and they should all be afforded the widest possible interpretation and vice versa.

The invention is not limited to the embodiments hereinbefore described but may be varied in both construction and detail.

1. A device comprising:
a first electrode;
a second electrode;
an active material positioned between the first and second electrode, wherein the active material comprises a plurality of randomly positioned conducting wires coated with a nanoscale surface passivation layer , said conducting wires are adapted to provide a conducting path or paths when a voltage is applied by one of the electrodes or between said electrodes; and
wherein the conductivity of the paths can be controlled by application of the applied voltage.

2. The device as claimed in claim 1 wherein the surface passivation layer comprises an oxide or other chemical functionalization.

3. The device as claimed in claim 1 wherein the active material comprises sparse random network of metallic or semiconducting nanowires or tubes and coated with a spacer layer of controlled composition.

4. The device as claimed in claim 1 wherein the active material comprises sparse random network of metallic or semiconducting nanowires or tubes and coated with a spacer layer of controlled composition and the spacer layer comprises at least one of: a passivation layer, electroactive material or some form of chemical functionalization.

5. The device as claimed in claim 1 wherein application of a bias voltage across the active material creates a randomly varying voltage distribution.

6. The device as claimed in claim 1 wherein application of a bias voltage across the active material creates a randomly varying voltage distribution that evolves in time, the rate of evolution being controlled by the applied voltage.

7. The device as claimed in claim 1 wherein the active material comprises a random nanowire network wherein connectivity and conductivity between nanowires can be arbitrarily controlled by the application of an electric field.

8. The device as claimed in claim 1 wherein the conductivity can be programmed to a set value.

9. The device as claimed in preceding claim 1 wherein conductivity and switching properties are length scale dependent.

10. The device as claimed in claim 1 wherein conductivity and switching properties are length scale dependent and the length scale dependent properties can be realised by interrogating with contact electrodes.

11. The device as claimed in claim 1 wherein the first electrode and second electrode are positioned at a distance apart such that the device is configured to operate as a unipolar resistive switch.

12. The device as claimed in claim 1 wherein the first electrode and second electrode are positioned at a distance apart such that the device is configured to operate as a unipolar resistive switch and the distance is approximately 20 μm or as dictated by the size of the nanowires.

13. The device as claimed in claim 1 wherein the first electrode and second electrode are positioned at a distance apart such that the device is configured to operate as a memristor device.

14. The device as claimed in claim 13 wherein the first electrode and second electrode are positioned at a distance apart such that the device is configured to operate as a memristor device and the distance is approximately 600 μm.

15. A resistive switching device comprising the device of claim 1.

16. An active material suitable for use between a first and second electrode, wherein the active material comprises a plurality of randomly positioned conducting wires and a passivation oxide layer, said conducting wires are adapted to provide a conducting path or paths when an electric field is applied by one of the electrodes or between said electrodes.

17. The active material of claim 16 wherein the conductivity of the paths can be arbitrarily controlled by application of the electric field.

18. The active material of claim 16 comprising a random nanowire network wherein connectivity and conductivity between nanowires can be arbitrarily controlled by the application of an electric field.

19. The active material of any of claims 16 wherein the conductivity can be programmed to a set value.

20. The active material of any of claim 16 wherein conductivity and switching properties are length scale dependent.

21. The active material as claimed in claim 16 wherein conductivity and switching properties are length scale dependent and the length scale dependent properties can be realised by interrogating with contact electrodes.

22. A resistive switching device comprising the active material of claim 1.
